(19) United States
(12) Patent Application Publication
(10) Pub. No.: US 2025/0383412 A1
(43) Pub. Date: Dec. 18, 2025

(54) IMAGE CAPTURE SYSTEM INCLUDING ACCESSORY DETECTION

(71) Applicant: GoPro, Inc., San Mateo, CA (US)

(72) Inventors: Herman Wong, Millbrae, CA (US); Paul Smith, San Diego, CA (US); Nicholas Vitale, Foster City, CA (US)

(21) Appl. No.: 18/741,305

(22) Filed: Jun. 12, 2024

(51) Int. Cl. G01R 33/07; G03B 17/08; G03B 17/12; G03B 17/56

(52) U.S. Cl. CPC G01R 33/072; G03B 17/08; G03B 17/12; G03B 17/561

(57) ABSTRACT

An image capture system that includes an image capture apparatus and an accessory that is configured for releasable connection to the image capture apparatus. The accessory is configured to generate a magnetic field that facilitates automatic detection and identification of the accessory by the image capture apparatus upon connection.

### TECHNICAL FIELD

The present disclosure relates to the automatic detection and identification of an accessory upon connection to an image capture apparatus.

### BACKGROUND

Image capture apparatuses are used in a variety of applications (e.g., handheld cameras and video recorders, cell phones, drones, etc.). Over time, a variety of accessories (e.g., lens attachments, audio components, illumination components, etc.) have been developed in order to vary the operation of an image capture apparatus and allow for more robust usage.

Known image capture apparatuses and accessories typically require the user to manually reconfigure(update) various settings on the image capture apparatus in order to allow and/or improve use of the accessory. Manually reconfiguring the image capture apparatus, however, not only detracts from the user’s overall experience by consuming time that could otherwise be spent on image and video capture but creates the potential for suboptimal operation in the event that the settings on the image capture apparatus are improperly configured for the particular accessory.

The present disclosure addresses this shortcoming by facilitating the automatic detection and identification of an accessory upon connection to an image capture apparatus as well as the automatic reconfiguration of various settings on the image capture apparatus based upon the detected accessory.

### SUMMARY

In one aspect of the present disclosure, an image capture system is disclosed that includes an image capture apparatus and an accessory that is configured for releasable connection to the image capture apparatus.

The image capture apparatus includes: a body that defines a waterproof internal compartment; at least one hall sensor that is positioned within the waterproof internal compartment; and a mounting member that is connected to the body, which includes a base and a collar that extends forwardly from the base.

The base defines at least one relief that extends along a height of the image capture apparatus.

The collar defines an arcuate channel and first and second stops that are positioned at opposite ends of the arcuate channel.

The accessory includes: a frame; an optical element that is supported by the frame; an alignment member that extends rearwardly from the frame and which is configured for engagement with the first and second stops such that the accessory is rotatable in relation to the mounting member through a fixed range of angular motion; and at least one magnet that is connected to the frame. The at least one magnet is configured to interface with the at least one hall sensor such that, upon connection of the accessory to the mounting member, the accessory is automatically detected and identified by the image capture apparatus based on output from the at least one hall sensor.

In certain embodiments, the at least one hall sensor may include first and second hall sensors that are spaced laterally along a width of the image capture apparatus.

In certain embodiments, the image capture apparatus may further include a heat sink, which is positioned within the body, and a flexible printed circuit assembly, which is connected to the heat sink.

In certain embodiments, the at least one hall sensor may be connected to the flexible printed circuit assembly.

In certain embodiments, the first and second stops may be separated by approximately 100 degrees to thereby define the fixed range of angular motion.

In certain embodiments, the alignment member and the at least one magnet may be positioned at opposite ends of the accessory.

In certain embodiments, the arcuate channel may be configured to receive the alignment member such that the alignment member is movable through the arcuate channel during rotation of the accessory.

In certain embodiments, the at least one magnet may be embedded within the accessory.

In certain embodiments, the frame may include at least one boss that is configured to receive the at least one magnet.

In certain embodiments, the at least one magnet may be mechanically secured within the at least one boss.

In another aspect of the present disclosure, an image capture system is disclosed that includes an image capture apparatus and an accessory.

The image capture apparatus includes a body and a mounting member that is connected to the body.

The accessory is configured for releasable connection to the image capture apparatus and generates a magnetic field that facilitates automatic detection and identification of the accessory by the image capture apparatus upon connection.

In certain embodiments, the image capture apparatus may further include at least one hall sensor, and the accessory may further include at least one magnet that is configured to interface with the at least one hall sensor.

In certain embodiments, the at least one hall sensor may include a first hall sensor and a second hall sensor, and the at least one magnet may include a first magnet and a second magnet.

In certain embodiments, the first hall sensor and the second hall sensor may be spaced laterally along a width of the image capture apparatus.

In certain embodiments, the mounting member may include a base that defines at least one relief.

In certain embodiments, the at least one relief may extend along height of the image capture apparatus and may be generally aligned with the at least one hall sensor and the at least one magnet so as to inhibit interference with the magnetic field.

In another aspect of the present disclosure, an image capture system is disclosed that includes an image capture apparatus and an accessory.

The image capture apparatus includes a body and a mounting member that is connected to the body.

The accessory is configured for releasable connection to the mounting member such that, upon connection of the accessory to the image capture apparatus, the accessory is rotatable in relation to the mounting member through a fixed range of angular motion and is automatically detected and identified by the image capture apparatus.

In certain embodiments, the body may include a base and a collar that extends forwardly from the base.

In certain embodiments, the collar may define first and second stops.

In certain embodiments, the accessory may include an alignment member that is configured for engagement with the first and second stops to thereby define the fixed range of angular motion.

In certain embodiments, the first and second stops may be separated by less than 180 degrees.

In certain embodiments, the base may define at least one relief that is configured to facilitate magnetic communication between the image capture apparatus and the accessory.

### BRIEF DESCRIPTION OF THE DRAWINGS

The present disclosure is best understood from the following detailed description when read in conjunction with the accompanying drawings. According to common practice, the various features of the drawings may not be to-scale, and the dimensions of the various features may be arbitrarily expanded or reduced. Additionally, in the interest of clarity, certain components, elements, and/or features may be omitted from certain drawings in the interest of clarity.

FIGS. 1A-1B are isometric views of an example of an image capture apparatus.

FIGS. 2A-2B are isometric views of another example of an image capture apparatus.

FIG. 3 is a top view of another example of an image capture apparatus.

FIG. 4 is a block diagram of electronic components of an image capture apparatus.

FIG. 5 is a front, perspective view of an image capture system according to the principles of the present disclosure, which includes another example of an image capture apparatus and an accessory that is configured for use therewith.

FIG. 6 is a front, perspective view of the image capture system seen in FIG. 5 with the image capture apparatus shown separated.

FIG. 7 is a partial, front, plan view of the image capture apparatus seen in FIG. 5.

FIG. 8 is a front, perspective view of a flexible printed circuit assembly of the image capture apparatus seen in FIG. 5.

FIG. 9 is a rear, perspective view of the accessory shown partially separated.

FIG. 10 is a partial, front, perspective view of the image capture apparatus seen in FIG. 5 and the accessory with the accessory rotated counterclockwise.

FIG. 11 is a rear, plan view of the image capture apparatus seen in FIG. 5 and the accessory with the accessory rotated counterclockwise.

FIG. 12 is a partial, front, perspective view of the image capture apparatus seen in FIG. 5 and the accessory with the accessory rotated clockwise.

FIG. 13 is a rear, plan view of the image capture apparatus seen in FIG. 5 and the accessory with the accessory rotated clockwise.

FIG. 14 is a chart illustrating the detection and identification of various embodiments of the accessory.

### DETAILED DESCRIPTION

The present disclosure describes an image capture apparatus and an accessory for use therewith. The accessory includes (one or more) at least one magnet, which generates a magnetic field, and the image capture apparatus includes (one or more) at least one hall sensor, which interfaces (interacts) with the magnet(s) in order to detect and/or measure changes in voltage when exposed to the magnetic field(s). The changes in voltage are utilized to detect and identify the accessory, which facilitates automatic reconfiguration of various settings on the image capture apparatus based upon the detected accessory in order to improve (e.g., optimize) image and/or video capture.

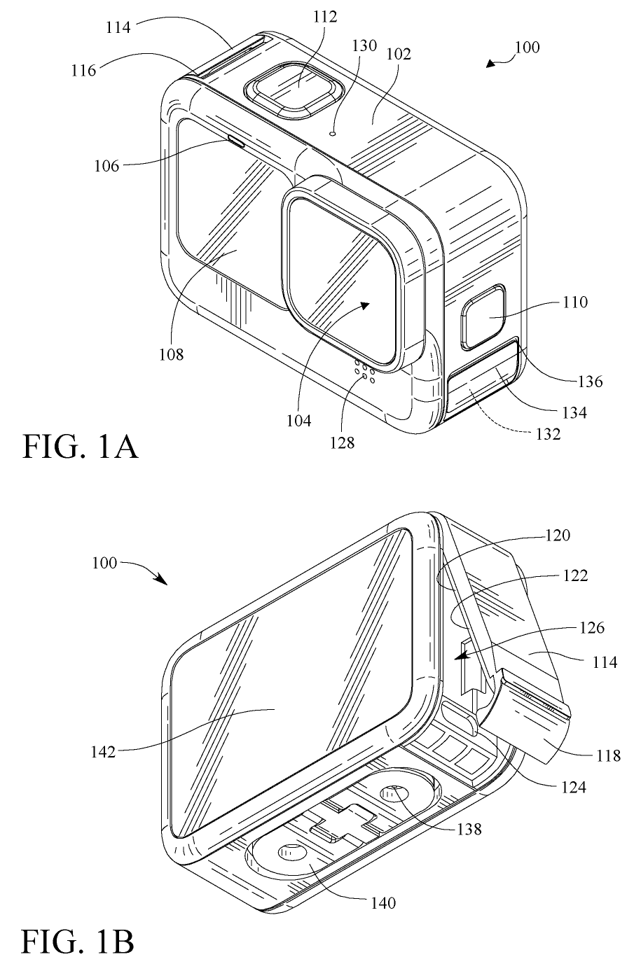

FIGS. 1A–1B are isometric views of an example of an image capture apparatus 100. The image capture apparatus 100 includes a body 102, an image capture device 104, an indicator 106, a display 108, a mode button 110, a shutter button 112, a door 114, a hinge mechanism 116, a latch mechanism 118, a seal 120, a battery interface 122, a data interface 124, a battery receptacle 126, microphones 128, 130, 132, a speaker 138, an interconnect mechanism 140, and a display 142. Although not expressly shown in FIGS. 1A–1B, the image capture apparatus 100 includes internal electronics, such as imaging electronics, power electronics, and the like, internal to the body 102 for capturing images and performing other functions of the image capture apparatus 100. The arrangement of the components of the image capture apparatus 100 shown in FIGS. 1A–1B is an example, other arrangements of elements may be used, except as is described herein or as is otherwise clear from context.

The body 102 of the image capture apparatus 100 may be made of a rigid material such as plastic, aluminum, steel, or fiberglass. Other materials may be used. The image capture device 104 is structured on a front surface of, and within, the body 102. The image capture device 104 includes a lens. The lens of the image capture device 104 receives light incident upon the lens of the image capture device 104 and directs the received light onto an image sensor of the image capture device 104 internal to the body 102. The image capture apparatus 100 may capture one or more images, such as a sequence of images, such as video. The image capture apparatus 100 may store the captured images and video for subsequent display, playback, or transfer to an external device. Although one image capture device 104 is shown in FIG. 1A, the image capture apparatus 100 may include multiple image capture devices, which may be structured on respective surfaces of the body 102.

As shown in FIG. 1A, the image capture apparatus 100 includes the indicator 106 structured on the front surface of the body 102. The indicator 106 may output, or emit, visible light, such as to indicate a status of the image capture apparatus 100. For example, the indicator 106 may be a light-emitting diode (LED). Although one indicator 106 is shown in FIG. 1A, the image capture apparatus 100 may include multiple indicators structured on respective surfaces of the body 102.

As shown in FIG. 1A, the image capture apparatus 100 includes the display 108 structured on the front surface of the body 102. The display 108 outputs, such as presents or displays, such as by emitting visible light, information, such as to show image information such as image previews, live video capture, or status information such as battery life, camera mode, elapsed time, and the like. In some implementations, the display 108 may be an interactive display, which may receive, detect, or capture input, such as user input representing user interaction with the image capture apparatus 100. In some implementations, the display 108 may be omitted or combined with another component of the image capture apparatus 100.

As shown in FIG. 1A, the image capture apparatus 100 includes the mode button 110 structured on a side surface of the body 102. Although described as a button, the mode button 110 may be another type of input device, such as a switch, a toggle, a slider, or a dial. Although one mode button 110 is shown in FIG. 1A, the image capture apparatus 100 may include multiple mode, or configuration, buttons structured on respective surfaces of the body 102. In some implementations, the mode button 110 may be omitted or combined with another component of the image capture apparatus 100. For example, the display 108 may be an interactive, such as touchscreen, display, and the mode button 110 may be physically omitted and functionally combined with the display 108.

As shown in FIG. 1A, the image capture apparatus 100 includes the shutter button 112 structured on a top surface of the body 102. The shutter button 112 may be another type of input device, such as a switch, a toggle, a slider, or a dial. The image capture apparatus 100 may include multiple shutter buttons structured on respective surfaces of the body 102. In some implementations, the shutter button 112 may be omitted or combined with another component of the image capture apparatus 100.

The mode button 110, the shutter button 112, or both, obtain input data, such as user input data in accordance with user interaction with the image capture apparatus 100. For example, the mode button 110, the shutter button 112, or both, may be used to turn the image capture apparatus 100 on and off, scroll through modes and settings, and select modes and change settings.

As shown in FIG. 1B, the image capture apparatus 100 includes the door 114 coupled to the body 102, such as using the hinge mechanism 116 (FIG. 1A). The door 114 may be connected (secured) to the body 102 using the latch mechanism 118 that releasably engages (contacts) the body 102 at a position generally opposite the hinge mechanism 116. The door 114 includes the seal 120 and the battery interface 122. Although one door 114 is shown in FIG. 1A, the image capture apparatus 100 may include multiple doors respectively forming respective surfaces of the body 102, or portions thereof. The door 114 may be removable from the body 102 by releasing the latch mechanism 118 from the body 102 and decoupling the hinge mechanism 116 from the body 102.

In FIG. 1B, the door 114 is shown in a partially open position such that the data interface 124 is accessible for communicating with external devices and the battery receptacle 126 is accessible for placement or replacement of a battery. In FIG. 1A, the door 114 is shown in a closed position. In implementations in which the door 114 is in the closed position, the seal 120 engages (contacts) a flange (not shown) to provide an environmental seal and the battery interface 122 engages (contacts) the battery (not shown) to secure the battery in the battery receptacle 126.

As shown in FIG. 1B, the image capture apparatus 100 includes the battery receptacle 126 structured to form a portion of an interior surface of the body 102. The battery receptacle 126 includes operative connections for power transfer between the battery and the image capture apparatus 100. In some implementations, the battery receptable 126 may be omitted. The image capture apparatus 100 may include multiple battery receptacles.

As shown in FIG. 1A, the image capture apparatus 100 includes a first microphone 128 structured on a front surface of the body 102, a second microphone 130 structured on a top surface of the body 102, and a third microphone 132 structured on a side surface of the body 102. The third microphone 132, which may be referred to as a drain microphone and is indicated as hidden in dotted line, is positioned (located) behind a drain cover 134, surrounded by a drain channel 136, and can drain liquid from audio components of the image capture apparatus 100. The image capture apparatus 100 may include other microphones on other surfaces of the body 102. The microphones 128, 130, 132 receive and record audio, such as in conjunction with capturing video or separate from capturing video. In some implementations, one or more of the microphones 128, 130, 132 may be omitted or combined with other components of the image capture apparatus 100.

As shown in FIG. 1B, the image capture apparatus 100 includes the speaker 138 structured on a bottom surface of the body 102. The speaker 138 outputs or presents audio, such as by playing back recorded audio or emitting sounds associated with notifications. The image capture apparatus 100 may include multiple speakers structured on respective surfaces of the body 102.

As shown in FIG. 1B, the image capture apparatus 100 includes the interconnect mechanism 140 structured on a bottom surface of the body 102. The interconnect mechanism 140 removably connects (secures) the image capture apparatus 100 to an external structure, such as a handle grip, another mount, or a securing device. The interconnect mechanism 140 includes folding protrusions configured to move between a collapsed (nested) configuration as shown in FIG. 1B and an extended (open) configuration. The folding protrusions of the interconnect mechanism 140 in the extended configuration may be coupled to reciprocal protrusions of other devices such as handle grips, mounts, clips, or like devices. The image capture apparatus 100 may include multiple interconnect mechanisms structured on, or forming a portion of, respective surfaces of the body 102. In some implementations, the interconnect mechanism 140 may be omitted.

As shown in FIG. 1B, the image capture apparatus 100 includes the display 142 structured on, and forming a portion of, a rear surface of the body 102. The display 142 outputs, such as presents or displays, such as by emitting visible light, data, such as to show image information such as image previews, live video capture, or status information such as battery life, camera mode, elapsed time, and the like. In some implementations, the display 142 may be an interactive display, which may receive, detect, or capture input, such as user input representing user interaction with the image capture apparatus 100. The image capture apparatus 100 may include multiple displays structured on respective surfaces of the body 102, such as the displays 108, 142 shown in FIGS. 1A–1B. In some implementations, the display 142 may be omitted or combined with another component of the image capture apparatus 100.

The image capture apparatus 100 may include features or components other than those described herein, such as other buttons or interface features. In some implementations, interchangeable lenses, cold shoes, and hot shoes, or a combination thereof, may be coupled to or combined with the image capture apparatus 100. For example, the image capture apparatus 100 may communicate with an external device, such as an external user interface device, via a wired or wireless computing communication link, such as via the data interface 124. The computing communication link may be a direct computing communication link or an indirect computing communication link, such as a link including another device or a network, such as the Internet. The image capture apparatus 100 may transmit images to the external device via the computing communication link.

The external device may store, process, display, or combination thereof, the images. The external user interface device may be a computing device, such as a smartphone, a tablet computer, a smart watch, a portable computer, personal computing device, or another device or combination of devices configured to receive user input, communicate information with the image capture apparatus 100 via the computing communication link, or receive user input and communicate information with the image capture apparatus 100 via the computing communication link. The external user interface device may implement or execute one or more applications to manage or control the image capture apparatus 100. For example, the external user interface device may include an application for controlling camera configuration, video acquisition, video display, or any other configurable or controllable aspect of the image capture apparatus 100. In some implementations, the external user interface device may generate and share, such as via a cloud-based or social media service, one or more images or video clips. In some implementations, the external user interface device may display unprocessed or minimally processed images or video captured by the image capture apparatus 100 contemporaneously with capturing the images or video by the image capture apparatus 100, such as for shot framing or live preview.

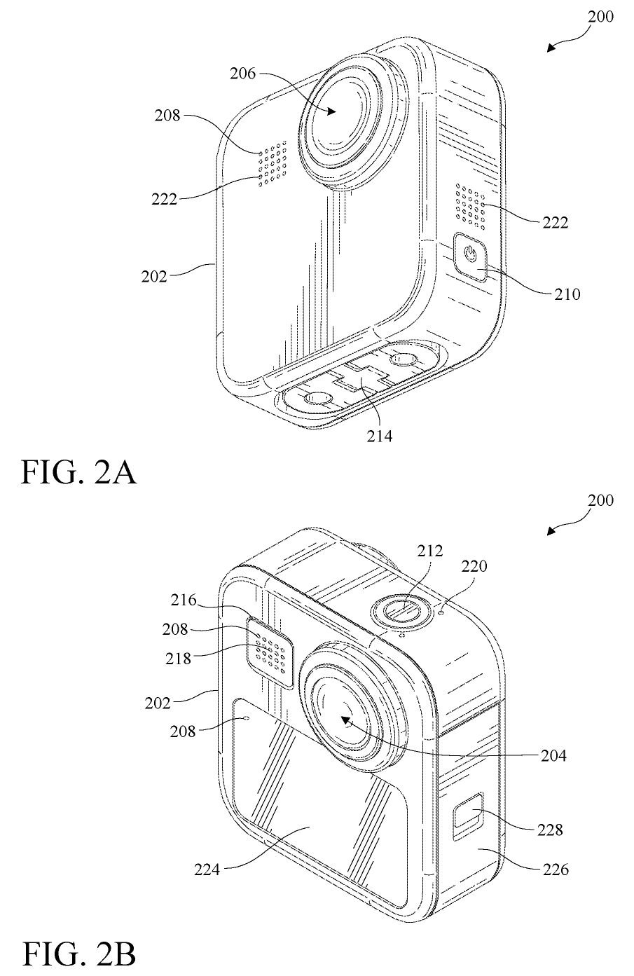

FIGS. 2A–2B illustrate another example of an image capture apparatus 200. The image capture apparatus 200 is similar to the image capture apparatus 100 shown in FIGS. 1A–1B. The image capture apparatus 200 includes a body 202, a first image capture device 204, a second image capture device 206, indicators 208, a mode button 210, a shutter button 212, an interconnect mechanism 214, a drainage channel 216, audio components 218, 220, 222, a display 224, and a door 226 including a release mechanism 228. The arrangement of the components of the image capture apparatus 200 shown in FIGS. 2A–2B is an example, other arrangements of elements may be used.

The body 202 of the image capture apparatus 200 may be similar to the body 102 shown in FIGS. 1A–1B. The first image capture device 204 is structured on a front surface of the body 202. The first image capture device 204 includes a first lens. The first image capture device 204 may be similar to the image capture device 104 shown in FIG. 1A. As shown in FIG. 2A, the image capture apparatus 200 includes the second image capture device 206 structured on a rear surface of the body 202. The second image capture device 206 includes a second lens. The second image capture device 206 may be similar to the image capture device 104 shown in FIG. 1A. The image capture devices 204, 206 are disposed on opposite surfaces of the body 202, for example, in a back-to-back configuration, Janus configuration, or offset Janus configuration. The image capture apparatus 200 may include other image capture devices structured on respective surfaces of the body 202.

As shown in FIG. 2B, the image capture apparatus 200 includes the indicators 208 associated with the audio component 218 and the display 224 on the front surface of the body 202. The indicators 208 may be similar to the indicator 106 shown in FIG. 1A. For example, one of the indicators 208 may indicate a status of the first image capture device 204 and another one of the indicators 208 may indicate a status of the second image capture device 206. Although two indicators 208 are shown in FIGS. 2A–2B, the image capture apparatus 200 may include other indicators structured on respective surfaces of the body 202.

As shown in FIGS. 2A–2B, the image capture apparatus 200 includes input mechanisms including the mode button 210, structured on a side surface of the body 202, and the shutter button 212, structured on a top surface of the body 202. The mode button 210 may be similar to the mode button 110 shown in FIG. 1B. The shutter button 212 may be similar to the shutter button 112 shown in FIG. 1A.

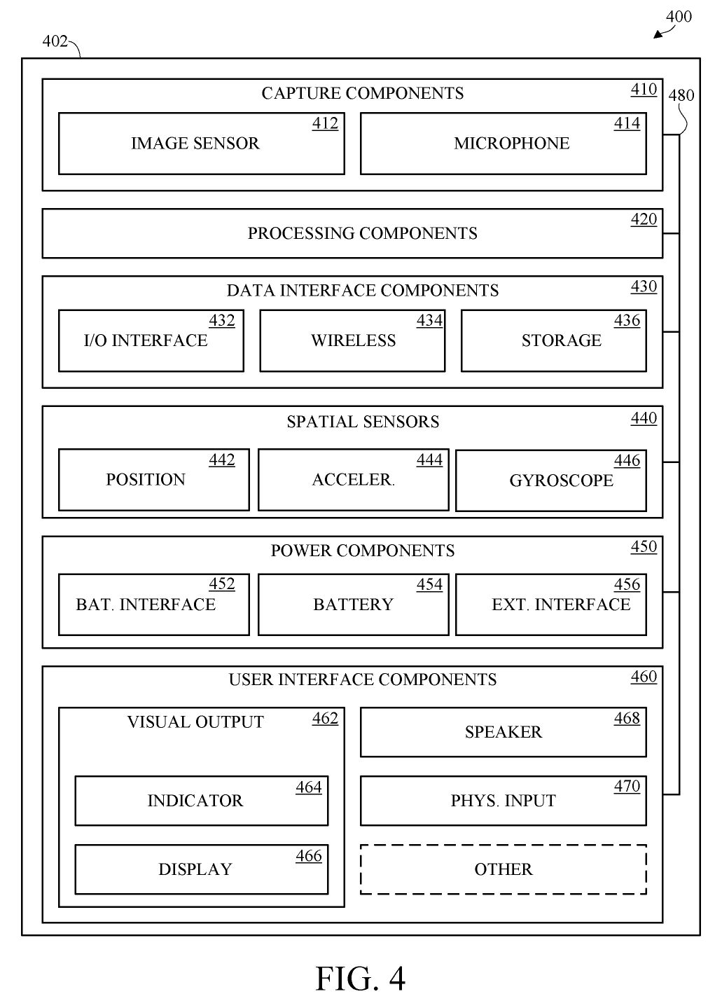

The image capture apparatus 200 includes internal electronics (not expressly shown), such as imaging electronics, power electronics, and the like, internal to the body 202 for capturing images and performing other functions of the image capture apparatus 200. An example showing internal electronics is shown in FIG. 4.

As shown in FIGS. 2A–2B, the image capture apparatus 200 includes the interconnect mechanism 214 structured on a bottom surface of the body 202. The interconnect mechanism 214 may be similar to the interconnect mechanism 140 shown in FIG. 1B.

As shown in FIG. 2B, the image capture apparatus 200 includes the drainage channel 216 for draining liquid from audio components of the image capture apparatus 200.

As shown in FIGS. 2A-2B, the image capture apparatus 200 includes the audio components 218, 220, 222, respectively structured on respective surfaces of the body 202. The audio components 218, 220, 222 may be similar to the microphones 128, 130, 132 and the speaker 138 shown in FIGS. 1A-1B. One or more of the audio components 218, 220, 222 may be, or may include, audio sensors, such as microphones, to receive and record audio signals, such as voice commands or other audio, in conjunction with capturing images or video. One or more of the audio components 218, 220, 222 may be, or may include, an audio presentation component that may present, or play, audio, such as to provide notifications or alerts.

As shown in FIGS. 2A–2B, a first audio component 218 is positioned (located) on a front surface of the body 202, a second audio component 220 is positioned (located) on a top surface of the body 202, and a third audio component 222 is positioned (located) on a back surface of the body 202. Other numbers and configurations for the audio components 218, 220, 222 may be used. For example, the audio component 218 may be a drain microphone surrounded by the drainage channel 216 and adjacent to one of the indicators 208 as shown in FIG. 2B.

As shown in FIG. 2B, the image capture apparatus 200 includes the display 224 structured on a front surface of the body 202. The display 224 may be similar to the displays 108, 142 shown in FIGS. 1A–1B. The display 224 may include an I/O interface. The display 224 may include one or more of the indicators 208. The display 224 may receive touch inputs. The display 224 may display image information during video capture. The display 224 may provide status information to a user, such as status information indicating battery power level, memory card capacity, time elapsed for a recorded video, etc. The image capture apparatus 200 may include multiple displays structured on respective surfaces of the body 202. In some implementations, the display 224 may be omitted or combined with another component of the image capture apparatus 200.

As shown in FIG. 2B, the image capture apparatus 200 includes the door 226 structured on, or forming a portion of, the side surface of the body 202. The door 226 may be similar to the door 114 shown in FIG. 1A. For example, the door 226 shown in FIG. 2A includes a release mechanism 228. The release mechanism 228 may include a latch, a button, or other mechanism configured to receive a user input that allows the door 226 to change position. The release mechanism 228 may be used to open the door 226 for a user to access a battery, a battery receptacle, an I/O interface, a memory card interface, etc.

In some embodiments, the image capture apparatus 200 may include features or components other than those described herein, some features or components described herein may be omitted, or some features or components described herein may be combined. For example, the image capture apparatus 200 may include additional interfaces or different interface features, interchangeable lenses, cold shoes, or hot shoes.

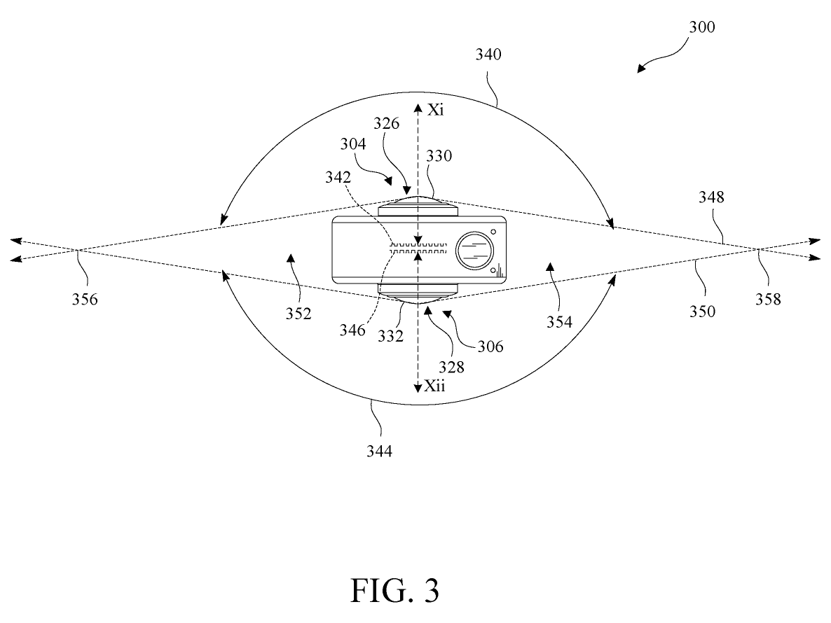

FIG. 3 is a top view of an image capture apparatus 300. The image capture apparatus 300 is similar to the image capture apparatus 200 of FIGS. 2A–2B and is configured to capture spherical images.

As shown in FIG. 3, a first image capture device 304 includes a first lens 330 and a second image capture device 306 includes a second lens 332. For example, the first image capture device 304 may capture a first image, such as a first hemispheric, or hyper-hemispherical, image, the second image capture device 306 may capture a second image, such as a second hemispheric, or hyper-hemispherical, image, and the image capture apparatus 300 may generate a spherical image incorporating or combining the first image and the second image, which may be captured concurrently, or substantially concurrently.

The first image capture device 304 defines a first field-of-view 340 wherein the first lens 330 of the first image capture device 304 receives light. The first lens 330 directs the received light corresponding to the first field-of-view 340 onto a first image sensor 342 of the first image capture device 304. For example, the first image capture device 304 may include a first lens barrel (not expressly shown), extending from the first lens 330 to the first image sensor 342. In the illustrated embodiment, the first lens 330 and the first image sensor 342 are integrated into a single unit, whereby the first image capture device 304 is configured as a first integrated sensor-lens assembly (ISLA) 326 that defines a first optical axis Xi.

The second image capture device 306 defines a second field-of-view 344 wherein the second lens 332 receives light. The second lens 332 directs the received light corresponding to the second field-of-view 344 onto a second image sensor 346 of the second image capture device 306. For example, the second image capture device 306 may include a second lens barrel (not expressly shown), extending from the second lens 332 to the second image sensor 346. In the illustrated embodiment, the second lens 332 and the second image sensor 346 are integrated into a single unit, whereby the second image capture device 306 is configured as a second ISLA 328 that defines a second optical axis Xii.

A boundary 348 of the first field-of-view 340 is shown using broken directional lines. A boundary 350 of the second field-of-view 344 is shown using broken directional lines. As shown, the image capture devices 304, 306 are arranged in a back-to-back (Janus) configuration such that the lenses 330, 332 face in opposite directions (e.g., a forward direction and a rearward direction), and such that the image capture apparatus 300 may capture spherical images. The first image sensor 342 captures a first hyper-hemispherical image plane from light entering the first lens 330. The second image sensor 346 captures a second hyper-hemispherical image plane from light entering the second lens 332.

As shown in FIG. 3, the fields-of-view 340, 344 partially overlap such that the combination of the fields-of-view 340, 344 forms a spherical field-of-view, except that one or more uncaptured areas 352, 354 may be outside of the fields-of-view 340, 344 of the lenses 330, 332. Light emanating from or passing through the uncaptured areas 352, 354, which may be proximal to the image capture apparatus 300, may be obscured from the lenses 330, 332 and the corresponding image sensors 342, 346, such that content corresponding to the uncaptured areas 352, 354 may be omitted from images captured by the image capture apparatus 300. In some implementations, the image capture devices 304, 306, or the lenses 330, 332 thereof, may be configured to minimize the uncaptured areas 352, 354.

Examples of points of transition, or overlap points, from the uncaptured areas 352, 354 to the overlapping portions of the fields-of-view 340, 344 are shown at 356, 358.

Images contemporaneously captured by the respective image sensors 342, 346 may be combined to form a combined image, such as a spherical image. Generating a combined image may include correlating the overlapping regions captured by the respective image sensors 342, 346, aligning the captured fields-of-view 340, 344, and stitching the images together to form a cohesive combined image. Stitching the images together may include correlating the overlap points 356, 358 with respective locations in corresponding images captured by the image sensors 342, 346. Although a planar view of the fields-of-view 340, 344 is shown in FIG. 3, the fields-of-view 340, 344 are hyper-hemispherical.

A change in the alignment, such as position, tilt, or a combination thereof, of the image capture devices 304, 306, such as of the lenses 330, 332, the image sensors 342, 346, or both, may change the relative positions of the respective fields-of-view 340, 344, may change the locations of the overlap points 356, 358, such as with respect to images captured by the image sensors 342, 346, and may change the uncaptured areas 352, 354, which may include changing the uncaptured areas 352, 354 unequally.

Incomplete or inaccurate information indicating the alignment of the image capture devices 304, 306, such as the locations of the overlap points 356, 358, may decrease the accuracy, efficiency, or both of generating a combined image. In some implementations, the image capture apparatus 300 may maintain information indicating the location and orientation of the image capture devices 304, 306, such as of the lenses 330, 332, the image sensors 342, 346, or both, such that the fields-of-view 340, 344, the overlap points 356, 358, or both may be accurately determined, which may improve the accuracy, efficiency, or both of generating a combined image.

The ISLAs 326, 328 (e.g., the lenses 330, 332) may be aligned as shown (e.g., such that the optical axes Xi, Xii are coincident with each other), laterally offset from each other (not shown), off-center from a central axis of the image capture apparatus 300 (not shown), or laterally offset and off-center from the central axis (not shown). Whether through use of offset or through use of compact image capture devices 304, 306, a reduction in distance between the lenses 330, 332 may improve the overlap in the fields-of-view 340, 344, such as by reducing the uncaptured areas 352, 354.

Images or frames captured by the image capture devices 304, 306 may be combined, merged, or stitched together to produce a combined image, such as a spherical or panoramic image, which may be an equirectangular planar image. In some implementations, generating a combined image may include use of techniques such as noise reduction, tone mapping, white balancing, or other image correction. In some implementations, pixels along a stitch boundary, which may correspond with the overlap points 356, 358, may be matched accurately to minimize boundary discontinuities.

FIG. 4 is a block diagram of electronic components in an image capture apparatus 400. The image capture apparatus 400 may be a single-lens image capture device, a multi-lens image capture device, or variations thereof, including an image capture apparatus with multiple capabilities such as the use of interchangeable integrated sensor lens assemblies. Components, such as electronic components, of the image capture apparatus 100 shown in FIGS. 1A–1B, the image capture apparatus 200 shown in FIGS. 2A–B, or the image capture apparatus 300 shown in FIG. 3, may be implemented as shown in FIG. 4.

The image capture apparatus 400 includes a body 402. The body 402 may be similar to the body 102 shown in FIGS. 1A–1B or the body 202 shown in FIGS. 2A–2B. The body 402 includes electronic components such as capture components 410, processing components 420, data interface components 430, spatial sensors 440, power components 450, user interface components 460, and a bus 480.

The capture components 410 include an image sensor 412 for capturing images. Although one image sensor 412 is shown in FIG. 4, the capture components 410 may include multiple image sensors. The image sensor 412 may be similar to the image sensors 342, 346 shown in FIG. 3. The image sensor 412 may be, for example, a charge-coupled device (CCD) sensor, an active pixel sensor (APS), a complementary metal–oxide–semiconductor (CMOS) sensor, or an N-type metal–oxide–semiconductor (NMOS) sensor. The image sensor 412 detects light, such as within a defined spectrum, such as the visible light spectrum or the infrared spectrum, incident through a corresponding lens such as the first lens 330 with respect to the first image sensor 342 or the second lens 332 with respect to the second image sensor 346 as shown in FIG. 3. The image sensor 412 captures detected light as image data and conveys the captured image data as electrical signals (image signals or image data) to the other components of the image capture apparatus 400, such as to the processing components 420, such as via the bus 480.

The capture components 410 include a microphone 414 for capturing audio. Although one microphone 414 is shown in FIG. 4, the capture components 410 may include multiple microphones. The microphone 414 detects and captures, or records, sound, such as sound waves incident upon the microphone 414. The microphone 414 may detect, capture, or record sound in conjunction with capturing images by the image sensor 412. The microphone 414 may detect sound to receive audible commands to control the image capture apparatus 400. The microphone 414 may be similar to the microphones 128, 130, 132 shown in FIGS. 1A–1B or the audio components 218, 220, 222 shown in FIGS. 2A–2B.

The processing components 420 perform image signal processing, such as filtering, tone mapping, or stitching, to generate, or obtain, processed images, or processed image data, based on image data obtained from the image sensor 412. The processing components 420 may include one or more processors having single or multiple processing cores. In some implementations, the processing components 420 may include, or may be, an application specific integrated circuit (ASIC) or a digital signal processor (DSP). For example, the processing components 420 may include a custom image signal processor. The processing components 420 conveys data, such as processed image data, with other components of the image capture apparatus 400 via the bus 480. In some implementations, the processing components 420 may include an encoder, such as an image or video encoder that may encode, decode, or both, the image data, such as for compression coding, transcoding, or a combination thereof.

Although not shown expressly in FIG. 4, the processing components 420 may include memory, such as a random-access memory (RAM) device, which may be non-transitory computer-readable memory. The memory of the processing components 420 may include executable instructions and data that can be accessed by the processing components 420.

The data interface components 430 communicates with other, such as external, electronic devices, such as a remote control, a smartphone, a tablet computer, a laptop computer, a desktop computer, or an external computer storage device. For example, the data interface components 430 may receive commands to operate the image capture apparatus 400. In another example, the data interface components 430 may transmit image data to transfer the image data to other electronic devices. The data interface components 430 may be configured for wired communication, wireless communication, or both. As shown, the data interface components 430 include an I/O interface 432, a wireless data interface 434, and a storage interface 436. In some implementations, one or more of the I/O interface 432, the wireless data interface 434, or the storage interface 436 may be omitted or combined.

The I/O interface 432 may send, receive, or both, wired electronic communications signals. For example, the I/O interface 432 may be a universal serial bus (USB) interface, such as USB type-C interface, a high-definition multimedia interface (HDMI), a FireWire interface, a digital video interface link, a display port interface link, a Video Electronics Standards Associated (VESA) digital display interface link, an Ethernet link, or a Thunderbolt link. Although one I/O interface 432 is shown in FIG. 4, the data interface components 430 include multiple I/O interfaces. The I/O interface 432 may be similar to the data interface 124 shown in FIG. 1B.

The wireless data interface 434 may send, receive, or both, wireless electronic communications signals. The wireless data interface 434 may be a Bluetooth interface, a ZigBee interface, a Wi-Fi interface, an infrared link, a cellular link, a near field communications (NFC) link, or an Advanced Network Technology interoperability (ANT+) link. Although one wireless data interface 434 is shown in FIG. 4, the data interface components 430 include multiple wireless data interfaces. The wireless data interface 434 may be similar to the data interface 124 shown in FIG. 1B.

The storage interface 436 may include a memory card connector, such as a memory card receptacle, configured to receive and operatively couple to a removable storage device, such as a memory card, and to transfer, such as read, write, or both, data between the image capture apparatus 400 and the memory card, such as for storing images, recorded audio, or both captured by the image capture apparatus 400 on the memory card. Although one storage interface 436 is shown in FIG. 4, the data interface components 430 include multiple storage interfaces. The storage interface 436 may be similar to the data interface 124 shown in FIG. 1B.

The spatial, or spatiotemporal, sensors 440 detect the spatial position, movement, or both, of the image capture apparatus 400. As shown in FIG. 4, the spatial sensors 440 include a position sensor 442, an accelerometer 444, and a gyroscope 446. The position sensor 442, which may be a global positioning system (GPS) sensor, may determine a geospatial position of the image capture apparatus 400, which may include obtaining, such as by receiving, temporal data, such as via a GPS signal. The accelerometer 444, which may be a three-axis accelerometer, may measure linear motion, linear acceleration, or both of the image capture apparatus 400. The gyroscope 446, which may be a three-axis gyroscope, may measure rotational motion, such as a rate of rotation, of the image capture apparatus 400. In some implementations, the spatial sensors 440 may include other types of spatial sensors. In some implementations, one or more of the position sensor 442, the accelerometer 444, and the gyroscope 446 may be omitted or combined.

The power components 450 distribute electrical power to the components of the image capture apparatus 400 for operating the image capture apparatus 400. As shown in FIG. 4, the power components 450 include a battery interface 452, a battery 454, and an external power interface 456 (ext. interface). The battery interface 452 (bat. interface) operatively couples to the battery 454, such as via conductive contacts to transfer power from the battery 454 to the other electronic components of the image capture apparatus 400. The battery interface 452 may be similar to the battery receptacle 126 shown in FIG. 1B. The external power interface 456 obtains or receives power from an external source, such as a wall plug or external battery, and distributes the power to the components of the image capture apparatus 400, which may include distributing power to the battery 454 via the battery interface 452 to charge the battery 454. Although one battery interface 452, one battery 454, and one external power interface 456 are shown in FIG. 4, any number of battery interfaces, batteries, and external power interfaces may be used. In some implementations, one or more of the battery interface 452, the battery 454, and the external power interface 456 may be omitted or combined. For example, in some implementations, the external interface 456 and the I/O interface 432 may be combined.

The user interface components 460 receive input, such as user input, from a user of the image capture apparatus 400, output, such as display or present, information to a user, or both receive input and output information, such as in accordance with user interaction with the image capture apparatus 400.

As shown in FIG. 4, the user interface components 460 include visual output components 462 to visually communicate information, such as to present captured images. As shown, the visual output components 462 include an indicator 464 and a display 466. The indicator 464 may be similar to the indicator 106 shown in FIG. 1A or the indicators 208 shown in FIGS. 2A–2B. The display 466 may be similar to the display 108 shown in FIG. 1A, the display 142 shown in FIG. 1B, or the display 224 shown in FIG. 2B. Although the visual output components 462 are shown in FIG. 4 as including one indicator 464, the visual output components 462 may include multiple indicators. Although the visual output components 462 are shown in FIG. 4 as including one display 466, the visual output components 462 may include multiple displays. In some implementations, one or more of the indicators 464 or the display 466 may be omitted or combined.

As shown in FIG. 4, the user interface components 460 include a speaker 468. The speaker 468 may be similar to the speaker 138 shown in FIG. 1B or the audio components 218, 220, 222 shown in FIGS. 2A–2B. Although one speaker 468 is shown in FIG. 4, the user interface components 460 may include multiple speakers. In some implementations, the speaker 468 may be omitted or combined with another component of the image capture apparatus 400, such as the microphone 414.

As shown in FIG. 4, the user interface components 460 include a physical input interface 470. The physical input interface 470 may be similar to the mode buttons 110, 210 shown in FIGS. 1A, 2A or the shutter buttons 112, 212 shown in FIGS. 1A, 2B. Although one physical input interface 470 is shown in FIG. 4, the user interface components 460 may include multiple physical input interfaces. In some implementations, the physical input interface 470 may be omitted or combined with another component of the image capture apparatus 400. The physical input interface 470 may be, for example, a button, a toggle, a switch, a dial, or a slider.

As shown in FIG. 4, the user interface components 460 include a broken line border box labeled “other” to indicate that components of the image capture apparatus 400 other than the components expressly shown as included in the user interface components 460 may be user interface components. For example, the microphone 414 may receive, or capture, and process audio signals to obtain input data, such as user input data corresponding to voice commands. In another example, the image sensor 412 may receive, or capture, and process image data to obtain input data, such as user input data corresponding to visible gesture commands. In another example, one or more of the spatial sensors 440, such as a combination of the accelerometer 444 and the gyroscope 446, may receive, or capture, and process motion data to obtain input data, such as user input data corresponding to motion gesture commands.

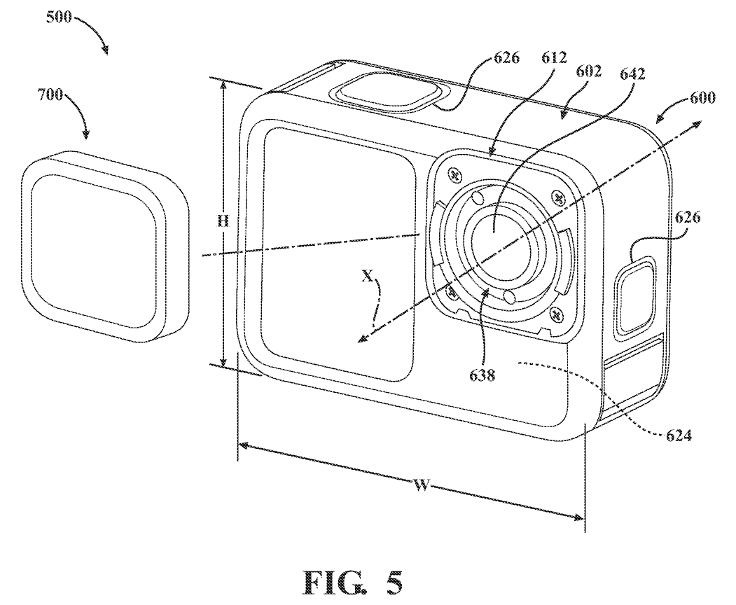

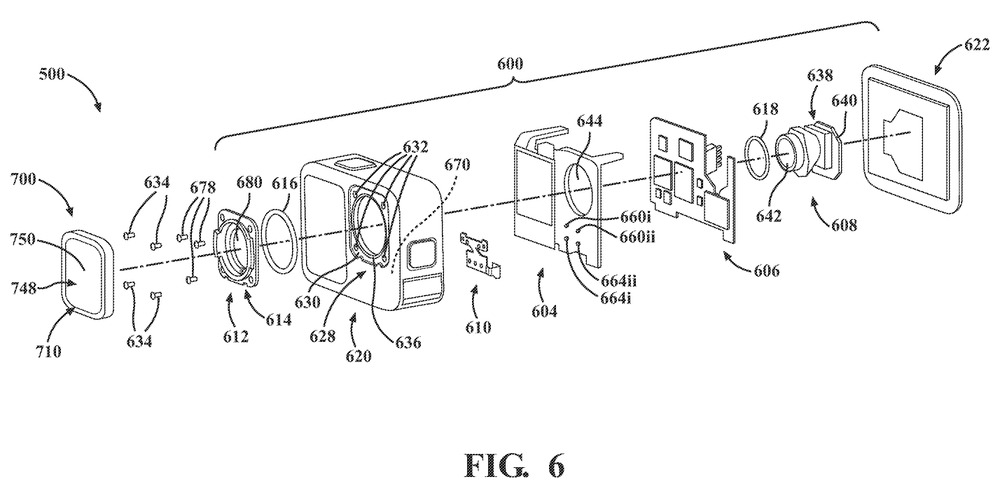

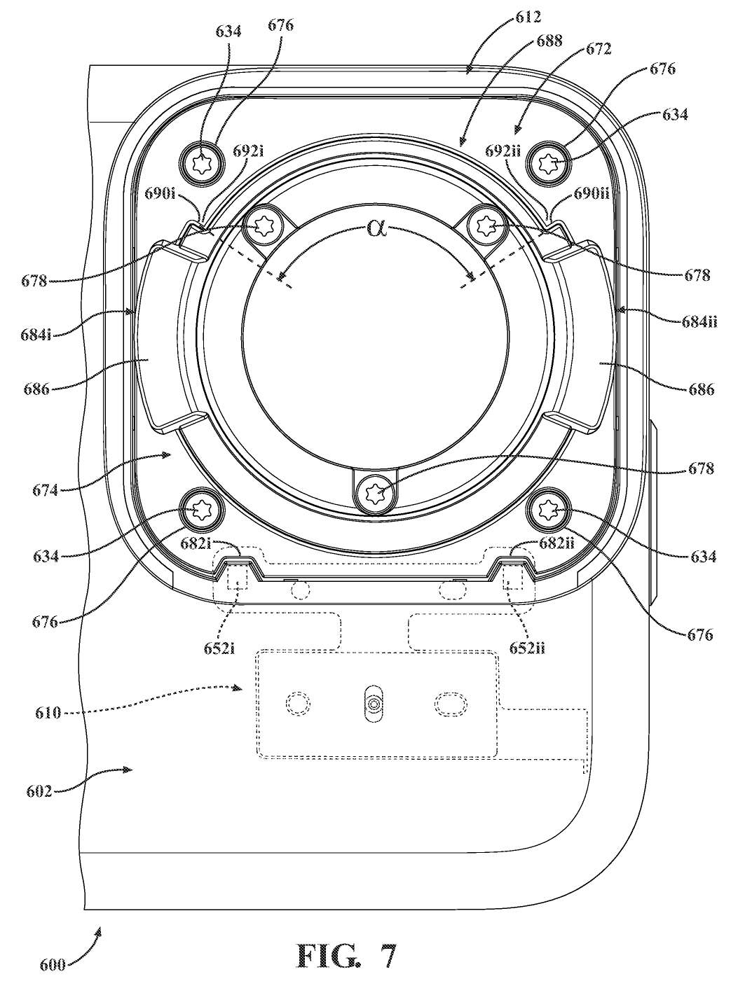

With reference now to FIGS. 5-7, an image capture system 500 is illustrated that includes an image capture apparatus 600 and an accessory 700 that is configured for use therewith. More specifically, FIG. 5 is a front, perspective view of the image capture system 500; FIG. 6 is a front, perspective view of the image capture system 500 with the image capture apparatus 600 shown separated; and FIG. 7 is a partial, front, plan view of the image capture apparatus 600.

Although the accessory 700 is generally illustrated and described as an optical component throughout the present disclosure, it is envisioned that the principles of the present disclosure may be applicable to a wide variety of accessories including, for example, an audio accessory, an illumination accessory (e.g., a light source), a display accessory, a mount, a housing for the image capture apparatus 600, etc.

The image capture apparatus 600 includes features similar to the aforedescribed image capture apparatuses 100 (FIGS. 1A, 1B), 200 (FIGS. 2A, 2B), 300 (FIG. 3), 400 (FIG. 4) and, accordingly, will only be discussed with respect to differences therefrom in the interest of brevity.

The image capture apparatus 600 includes: a body 602; a heat sink 604; a printed circuit board (PCB) module 606; an ISLA 608; a flexible printed circuit (FPC) assembly 610; a mounting member 612 (e.g., a bayonet 614); and respective front and rear (first and second) sealing members 616, 618.

The body 602 includes a front housing portion 620 and a rear housing portion 622 that is connected (secured) to the front housing portion 620 so as to define a (waterproof) internal compartment 624, which receives (accommodates) and protects the various internal components of the image capture apparatus 600 (e.g., the heat sink 604, the PCB module 606, the ISLA 608, and the FPC assembly 610).

The front housing portion 620 includes a plurality (series) of apertures 626, which are configured to receive (accommodate) various buttons, displays, etc., and a window 628, which is defined by a flange 630 and is configured to receive the mounting member 612, the sealing member 616, and the ISLA 608 and.

The flange 630 is configured in correspondence with the mounting member 612 (i.e., such that the flange 630 and the mounting member 612 include matching configurations that mirror each other), whereby the mounting member 612 seats within the window 628. The flange 630 includes a plurality (series) of apertures 632, which are configured to receive mechanical fasteners 634, and a channel 636, which is configured to receive the sealing member 616.

The heat sink 604 is positioned within the body 602 and is connected (secured) to (or otherwise supported by) the front housing portion 620. The heat sink 604 is configured to distribute thermal energy through the image capture apparatus 600 and, more specifically, distributes heat away from the PCB module 606 and the ISLA 608.

The PCB module 606 is connected (secured) to the heat sink 604 in either a fixed or removable fashion. The PCB module 606 supports various electrical and/or thermal components of the image capture apparatus 600 including, for example, a system-on-chip for the image capture apparatus 600, (one or more) at least one power management integrated circuit, (one or more) at least one integrated circuit (IC) (e.g., a WiFi IC, an embedded multi-media card, etc.), an SD card reader, etc. It should be appreciated, however, that partitioning (distribution) of the various electrical and/or thermal components throughout the image capture apparatus 600 may be dependent upon a variety of factors, including, for example, the area available on different sections of the PCB module 606.

The ISLA 608 receives and focuses light and converts captured content into an electronic image signal that is processed to form an image. The ISLA 608 defines an optical axis X (FIG. 5) and includes a body 638 that supports (one or more) at least one image sensor 640, which is similar or identical to the image sensor(s) 312 (FIG. 3), and (one or more) at least one lens 642, which receives and directs light onto the image sensor(s) 640 and is similar or identical to the lenses 330, 332.

The ISLA 608 extends through an opening 644 (FIG. 6) in the heat sink 604, which allows for direct connection (securement) of the ISLA 608 to the mounting member 612, and through the window 628 in the front housing portion 620. By directly connecting the ISLA 608 to the mounting member 612, physical, supportive connections between the ISLA 608 and the heat sink 604 can be reduced, thereby simplifying assembly of the image capture apparatus 600. Additionally, direct connection of the ISLA 608 to the mounting member 612, rather than via an intermediate component (e.g., the heat sink 604), enables precise alignment of the ISLA 608 and the mounting member 612, which enables precise alignment of the accessory 700, the mounting member 612, and the ISLA 608.

The sealing member 618 is positioned (located) between the mounting member 612 and the ISLA 608. More specifically, the sealing member 618 is positioned about and is supported by the ISLA 608. The sealing member 618 forms watertight seals with both the mounting member 612 and the ISLA 608 upon assembly of the image capture apparatus 600, thereby obviating any need to form a direct seal between the ISLA 608 and the front housing portion 620.

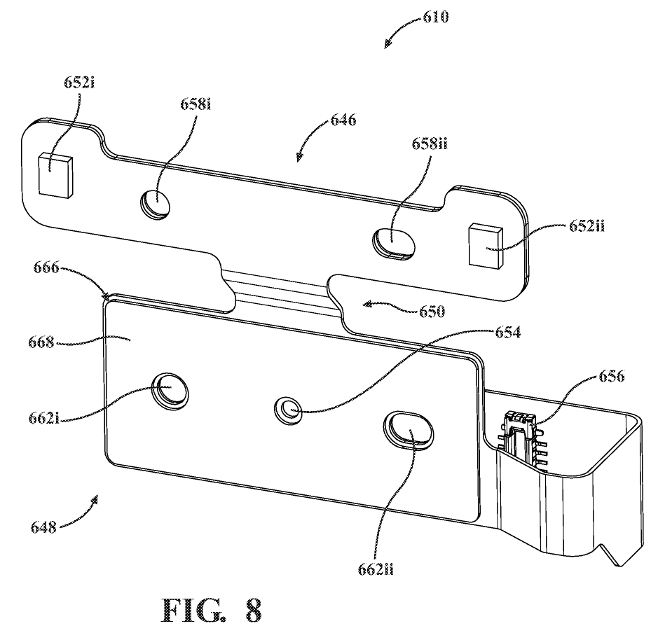

With reference now to FIG. 8 as well, the FPC assembly 610 will be discussed. More specifically, FIG. 8 is a front, perspective view of the FPC assembly 610, which is electrically connected to the PCB module 606 (FIG. 6) in a manner that facilitates the transfer of data therebetween. More specifically, the FPC assembly 610 is connected (secured, mounted) to the heat sink 604 such that the FPC assembly 610 is positioned (located) between the front housing portion 620 and the heat sink 604.

Although illustrated as being adhesively connected (secured) to the heat sink 604 in the illustrated embodiment, it is envisioned that the FPC assembly 610 may be connected (secured) to the heat sink 604 in any manner suitable for the intended purpose of inhibiting (if not entirely preventing) relative movement therebetween. For example, embodiments in which the FPC assembly 610 may be mechanically connected (secured) to the heat sink 604 are also envisioned herein and would not be beyond the scope of the present disclosure.

The FPC assembly 610 includes: respective upper and lower (first and second) wings 646, 648; a bridge 650; (one or more) at least one hall sensor 652; a microphone subassembly 654; and an electrical connector 656.

The upper wing 646 includes a pair of (upper) apertures 658i, 658ii and supports the hall sensor(s) 652 such that the hall sensor(s) 652 are concealed (positioned, located) within the body 602 of the image capture apparatus 600 (i.e., within the internal compartment 624). The apertures 658i, 658ii are configured to receive corresponding (upper) alignment members 660i, 660ii on the heat sink 604 in order to facilitate proper orientation (registration) of the FPC assembly 610 within the internal compartment 624 and proper alignment between the FPC assembly 610 and the heat sink 604. Although shows as including two apertures 658 in the illustrated embodiment, it is envisioned that the particular number of apertures 658 may be varied without departing from the scope of the present disclosure (e.g., depending upon the particular configuration of the heat sink 604).

The lower wing 648 supports the microphone subassembly 654 and the electrical connector 656, which facilitates electrical communication (e.g., the communication of data and/or power) between the FPC assembly 610 and the PCB module 606, and includes a pair of (lower) apertures 662i, 662ii that are configured to receive corresponding (lower) alignment members 664i, 664ii on the heat sink 604 in order to further facilitate proper orientation (registration) of the FPC assembly 610 within the internal compartment 624 and proper alignment between the FPC assembly 610 and the heat sink 604. Although shows as including two apertures 662 in the illustrated embodiment, it is envisioned that the particular number of apertures 662 may be varied without departing from the scope of the present disclosure (e.g., depending upon the particular configuration of the heat sink 604).

In the illustrated embodiment, the lower wing 648 further includes (one or more) at least one stiffening member 666, which increases the strength (rigidity) of the lower wing 648. Although illustrated as a metallic (e.g., stainless steel) plate 668 that is adhesively connected (secured) to the lower wing 648, it is envisioned that the particular configuration of the stiffening member(s) 666, the particular material(s) used in construction of the stiffening member(s) 666, and/or the manner in which the stiffening member(s) 666 is connected (secured) to the lower wing 648 may be varied. For example, embodiments in which the stiffening member(s) 666 may include a plurality of ribs are also envisioned herein, as are embodiments in which the stiffening member(s) 666 may include one or more non-metallic materials, and embodiments in which the stiffening member(s) 666 be mechanically connected (secured) to the lower wing 648.

The bridge 650 extends between and connects the respective upper and lower wings 646, 648, and imparts flexibility to the FPC assembly 610. More specifically, the bridge 650 allows for relative movement between the respective upper and lower wings 646, 648 in order to facilitate proper alignment between the FPC assembly 610 and the heat sink 604 and proper connection of the FPC assembly 610 to the heat sink 604.

In the illustrated embodiment, the FPC assembly 610 is integrally (unitarily, monolithically) formed such that the upper wing 646, the lower wing 648, and the bridge 650 are formed from a single piece of material (e.g., one or more metallic materials). Embodiments in which one or more of the upper wing 646, the lower wing 648, and the bridge 650 may be formed as separate, discrete components of the FPC assembly 610 are also envisioned herein, however, and would not be beyond the scope of the present disclosure.

The hall sensor(s) 652 are configured to measure changes in voltage when exposed to the magnetic field generated by the accessory 700, which is described in further detail below. The hall sensor(s) 652 are connected (secured) to (or otherwise supported by) the upper wing 646 of the FPC assembly 610, as indicated above, and are positioned (located) in adjacent relation to (e.g., in engagement (contact) with) an inner surface 670 (FIG. 6) of the front housing portion 620, which facilitates the measurement of any change in voltage (i.e., upon connection of the accessory 700).

Although illustrated as being adhesively connected (secured) to the upper wing 646 in the illustrated embodiment, it is envisioned that the hall sensor(s) 652 may be connected (secured) to the FPC assembly 610 in any manner suitable for the intended purpose of inhibiting (if not entirely preventing) relative movement therebetween. For example, embodiments in which the hall sensor(s) 652 may be mechanically connected (secured) to the FPC assembly 610 are also envisioned herein and would not be beyond the scope of the present disclosure.

In the illustrated embodiment, the image capture apparatus 600 includes a pair of (first and second) hall sensors 652i, 652ii, which are spaced laterally along a width W (FIG. 5) of the image capture apparatus 600. It is envisioned, however, that the particular number of hall sensors 652 and/or the orientations of the hall sensors 652 may be varied. For example, embodiments of the image capture apparatus 600 including fewer and greater numbers of hall sensor 652 are also envisioned herein (e.g., depending upon the particular configuration of the accessory 700) and would not be beyond the scope of the present disclosure.

The mounting member 612 is connected (secured) to the body 602 of the image capture apparatus 600 (i.e., the front housing portion 620) and supports the accessory 700 and the ISLA 608, each of which is configured for direct connection thereto. By directly connecting the ISLA 608 to the mounting member 612, physical, supportive connections between the ISLA 608 and the heat sink 604 can be reduced (if not entirely eliminated) so as to further simplify assembly of the image capture apparatus 600. The configuration of the mounting member 612 also eliminates any direct physical connection between the accessory 700 and the heat sink 604, which also simplifies sealing of the image capture apparatus 600. More specifically, by sealing the mounting member 612 to the front housing portion 620 (via the sealing member 900) and the ISLA 608 (via the sealing member 618), sealing can be localized to the mounting member 612, which allows the overall geometry and architecture of the image capture apparatus 600 to be simplified by eliminating the need for a perimeter seal about the heat sink 604. Moreover, the seals established between the mounting member 612, the front housing portion 620, and the ISLA 608 by the sealing members 616, 618 not only facilitate the establishment of a waterproof environment within the internal compartment 624, thereby protecting the various internal components of the image capture apparatus 600 (e.g., the FPC assembly 610, the hall sensor(s) 652, etc.), but allow the image capture apparatus 600 to remain watertight upon removal of the accessory 700.

The mounting member 612 includes: a base 672 (FIG. 7); a collar 674; and a plurality (series) of apertures 676, which extend therethrough and are configured to receive the mechanical fasteners 634 and mechanical fasteners 678, which respectively connect the mounting member 612 to the front housing portion 620 and the ISLA 608.

The base 672 is configured in correspondence with the flange 630 (FIG. 6) such that the base 672 seats within the front housing portion 620 upon assembly of the image capture apparatus 600. The base 672 is generally planar in configuration and defines a (central) opening 680 and (one or more) at least one relief (cutout) 682.

The opening 680 is configured to receive the ISLA 608 such that the ISLA 608 (i.e., the lens(es) 642 (FIG. 6)) extend therethrough along the optical axis X (FIG. 5).

The relief(s) 682 extend (vertically) into the base 672 along (i.e., in generally parallel relation) to a height H (FIG. 5) of the image capture apparatus 600 and in generally orthogonal (perpendicular) relation to the optical axis X. The relief(s) 682 are generally aligned with the hall sensor(s) 652 (FIG. 8) and facilitate communication between the image capture apparatus 600 and the accessory 700, as described in further detail below.

Although shown as including two reliefs 682i, 682ii, it is envisioned that the particular number of reliefs 682 defined by the base 672 may be varied (e.g., depending upon the particular number of hall sensor(s) 652). For example, embodiments in which the mounting member 612 may include a single relief 682 are also envisioned herein, as are embodiments in which the mounting member 612 may include three or more reliefs 682, and would not be beyond the scope of the present disclosure.

The collar 674 is generally annular in configuration and extends outwardly from the base 672 (i.e., forwardly towards the accessory 700) so as to circumscribe the opening 680 (FIG. 6). More specifically, upon assembly of the image capture apparatus 600, the collar 674 extends (is positioned, located) externally of (protrudes beyond) the front housing portion 620, which facilitates connection of the accessory 700 thereto, as described in further detail below. The collar 674 includes a pair of radial mounts 684 (e.g., ears 686) and defines an (arcuate) channel (recess) 688, which extends into the collar 674, as well as (first and second) stops 690i, 690ii.

The radial mounts 684 are formed integrally (unitarily, monolithically) with the collar 674 and extend radially (laterally) outward therefrom. The radial mounts 684 are configured for releasable engagement with the accessory 700 such that the accessory 700 is (repeatably) connectable to and disconnectable from the image capture apparatus 600 via the mounting member 612. While the collar 674 is illustrated as including a pair of diametrically opposed radial mounts 684i, 684ii in the illustrated embodiment, it should be appreciated that the particular number, location, and/or configuration of the radial mounts 684 may be varied in alternate embodiments without departing from the scope of the present disclosure (e.g., depending upon the particular configuration of the accessory 700).

The stops 690i, 690ii are positioned (located) at opposite ends 692i, 692ii of the channel 688, respectively, such that the channel 688 extends therebetween. In the illustrated embodiment, the mounting member 612 (i.e., the channel 688) is configured such that the stops 690i, 690ii are separated by an angular (circumferential) distance α (FIG. 7) that is less than 180 degrees. More specifically, the mounting member 612 is configured such that the angular distance α lies substantially within the range of approximately 80 degrees to approximately 120 degrees (e.g., approximately 100 degrees).

As described in further detail below, the channel 688 receives the accessory 700 and facilitates rotation thereof in relation to the mounting member 612, and the stops 690i, 690ii are configured for engagement (contact) with the accessory 700 to restrict rotation thereof to a fixed range of angular (rotational) motion that corresponds to the angular distance α. As such, in the illustrated embodiment, the range of angular (rotational) motion for the accessory 700 is less than 180 degrees and lies substantially within the range of approximately 80 degrees to approximately 120 degrees (e.g., approximately 100 degrees). Embodiments in which the mounting member 612 may be configured such that the angular distance α and, thus, the range of angular (rotational) motion for the accessory 700, lies outside the disclosed range are also envisioned herein (e.g., depending upon the particular configuration of the image capture apparatus 600 and/or the accessory 700), however, and would not be beyond the scope of the present disclosure.

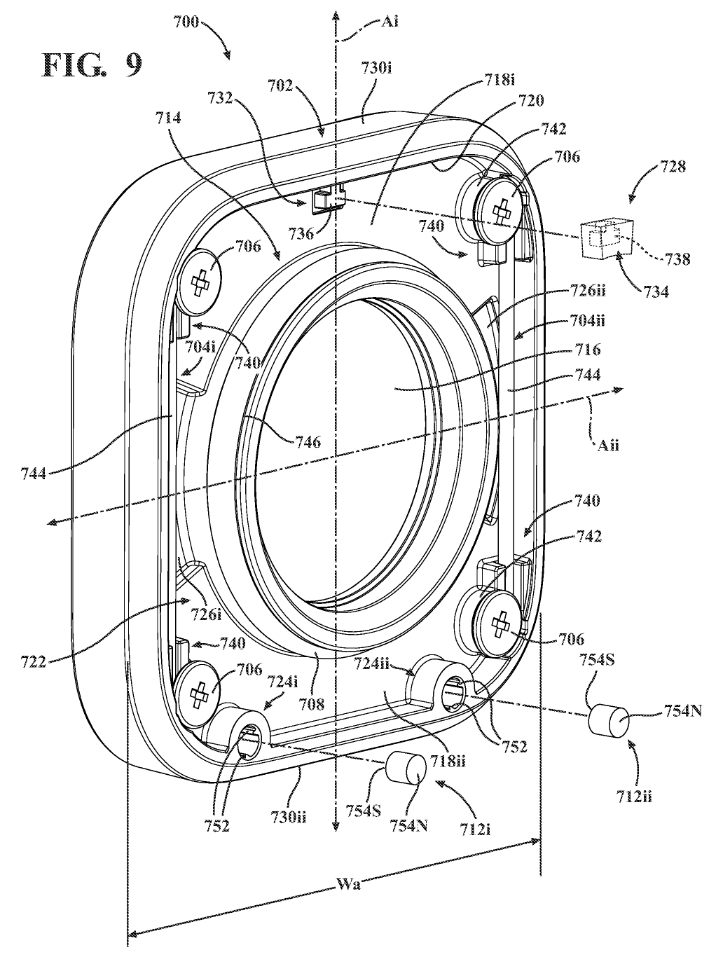

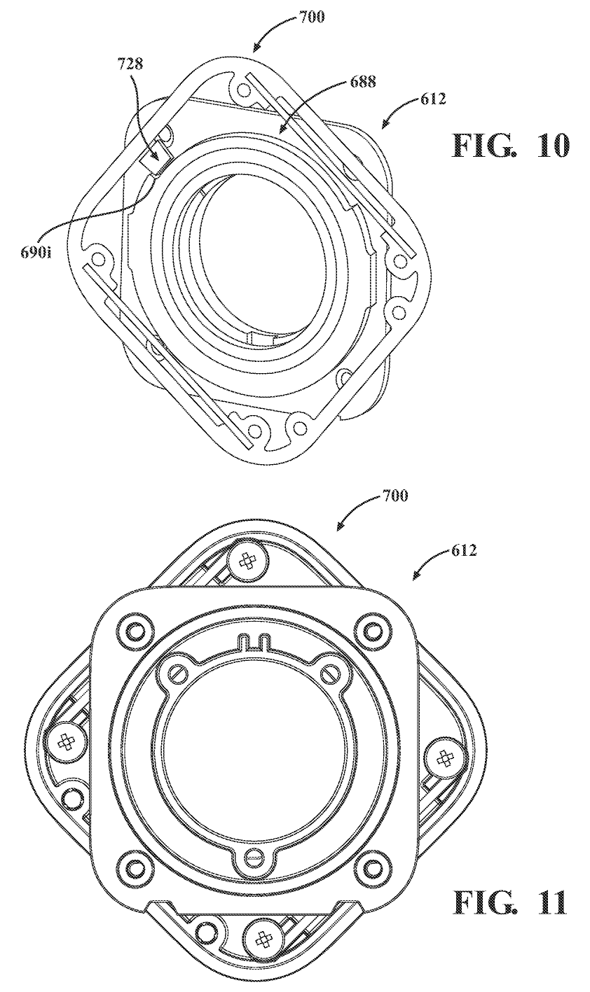

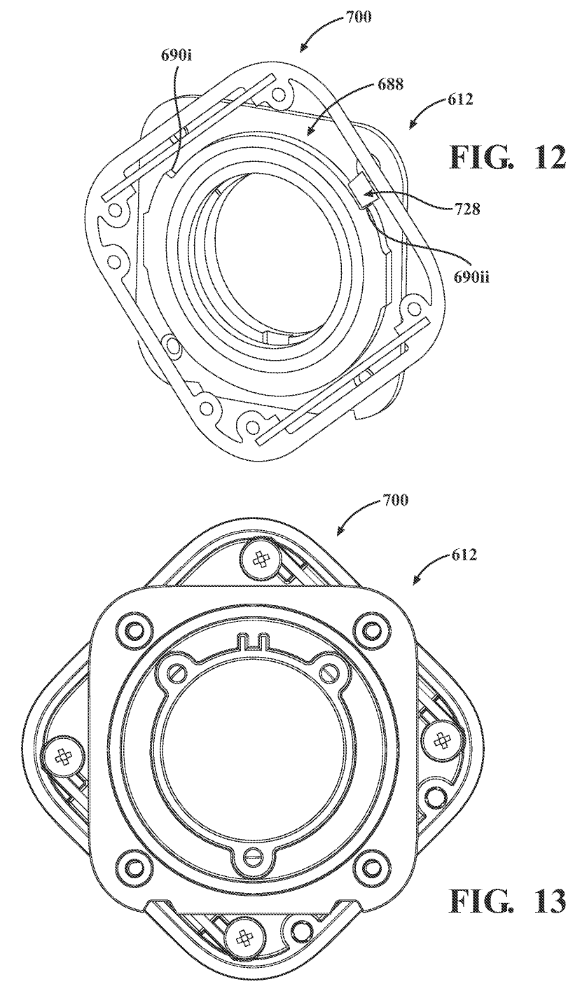

With reference now to FIGS. 9-13 as well, the accessory 700 will be discussed. More specifically, FIG. 9 is a rear, perspective view of the accessory 700; FIG. 10 is a partial, front, perspective view of the image capture apparatus 600 and the accessory 700 with the accessory 700 rotated counterclockwise; FIG. 11 is a rear, plan view of the image capture apparatus 600 and the accessory 700 with the accessory 700 rotated counterclockwise; FIG. 12 is a partial, front, perspective view of the image capture apparatus 600 and the accessory 700 with the accessory 700 rotated clockwise; and FIG. 13 is a rear, plan view of the image capture apparatus 600 and the accessory 700 with the accessory 700 rotated clockwise.

The accessory 700 is configured for releasable connection to (engagement with) the image capture apparatus 600 (i.e., via the mounting member 612 (FIGS. 6, 7)) and functions as a removable cap that protects and conceals the ISLA 608. The accessory 700 includes: a frame 702; retainers 704i, 704ii that are connected to the frame 702 by mechanical fasteners 706; a sealing member 708; an insert 710 (FIG. 6); and (one or more) at least one magnet (magnetic member) 712. As seen in FIG. 9, the accessory 700 is symmetrical about a (first) axis Ai, which extends in generally parallel relation to the height H (FIG. 5) of the image capture apparatus 600, and asymmetrical about a (second) axis Aii, which extends in generally parallel relation to the width W of the image capture apparatus 600 and in generally orthogonal (perpendicular) relation to the axis Ai.

While the accessory 700 is shown as being generally square-shaped in configuration throughout the figures, it should be appreciated that the specific configuration of the accessory 700 may be varied in alternate embodiments without departing from the scope of the present disclosure (e.g., depending upon the particular configuration of the ISLA 608 and/or the body 602 of the image capture apparatus 600, the desired aesthetic appearance of the image capture apparatus 600, etc.).

The frame 702 receives and supports the insert 710 (FIG. 6) and defines a (generally annular) extension (barrel) 714, which includes an opening 716 and is generally centered on the frame 702. More specifically, the extension 714 extends rearwardly from the frame 702 (i.e., towards the body 602 of image capture apparatus 600) so as to define guide channels 718i, 718ii, which are positioned (located) between the extension 714 and an inner wall 720 of the frame 702 and are configured to receive the radial mounts 684 (FIG. 7) during connection of the accessory 700 to the image capture apparatus 600, as described in further detail below.

On a rear surface 722 thereof, the frame 702 includes: (one or more) at least one boss 724; recesses 726; and an alignment member 728.

The boss(es) 724 extend rearwardly from the frame 702 and are formed integrally (unitarily, monolithically) therewith. The boss(es) 724 receive (accommodate) the magnet(s) 712 such that the magnet(s) 712 are secured to the frame 702 via the boss(es) 724. More specifically, as seen in FIG. 9, the boss(es) 724 are positioned (located) between the retainers 704i, 704ii and adjacent to the perimeter of the accessory 700.

In the illustrated embodiment, the accessory 700 includes a pair of (first and second) bosses 724i, 724ii, which are spaced laterally along a width Wa of the accessory 700. It is envisioned, however, that the particular number of bosses 724 and/or the orientation of the bosses 724 may be varied. For example, embodiments of the accessory 700 including fewer or greater numbers of bosses 724 are also envisioned herein (e.g., depending upon the particular configuration of the image capture apparatus 600) and would not be beyond the scope of the present disclosure.

The recesses 726 include configurations corresponding to those defined by the radial mounts 684 (FIG. 7) such that, upon connection of the accessory 700 to the image capture apparatus 600 (i.e., the mounting member 612), the radial mounts 684 are received by (positioned within) the recesses 726. The recesses 726 thus act as locating features that facilitate proper orientation of the accessory 700 relative to the mounting member 612. The corresponding (complimentary) configurations of the recesses 726 and the radial mounts 684 not only facilitate proper connection and seating of the accessory 700, but increase stability of the accessory 700 upon connection to the image capture apparatus 600 to inhibit (if not entirely prevent) unintended relative movement therebetween (e.g., rattling, pivoting, etc.), which inhibits (if not entirely prevents) localized wear on the accessory 700 and/or the mounting member 612.

While the accessory 700 is illustrated as including a pair of diametrically opposed recesses 726i, 726ii in the illustrated embodiment, it should be appreciated that the particular number, location, and/or configuration of the recesses 726 may be varied in alternate embodiments without departing from the scope of the present disclosure (e.g., depending upon the particular configuration of the mounting member 612).

The alignment member 728 extends rearwardly from the frame 702 and is positioned (located) between the retainers 704i, 704ii and adjacent to the perimeter of the accessory 700. More specifically, the alignment member is positioned (located) adjacent to a (first) end (side) 730i of the frame 702 adjacent to the perimeter thereof.

The alignment member 728 is configured for insertion into the channel 688 (FIG. 7) such that the alignment member 728 is movable therethrough channel 688 as the accessory 700 rotates in relation to the image capture apparatus 600 (i.e., the mounting member 612) during connection and disconnection of the accessory 700. In addition, the alignment member 728 is configured for engagement (contact) with the stops 690i, 690ii so as to restrict (confine) rotation of the accessory 700 to the fixed range of angular (rotational) motion discussed above. More specifically, at one end of the fixed range of angular (rotational) motion, the alignment member 728 engages (contacts) the stop 690i (i.e., during counterclockwise rotation of the accessory 700), as seen in FIGS. 10 and 11, and at the other end of the fixed range of angular (rotational) motion, the alignment member 728 engages the stop 690ii (i.e., during clockwise rotation of the accessory 700), as seen in FIGS. 12 and 13.

In addition to facilitating rotation of the accessory 700 in relation to the image capture apparatus 600, the interface between the alignment member 728 and the channel 688 restricts the accessory 700 to connection in a single orientation. More specifically, attempting to connect the accessory 700 in an alternate orientation (e.g., an orientation in which the accessory 700 is rotated 180 degrees from that which is illustrated in FIG. 9) would result in engagement (contact) between the alignment member 728 and the collar 674, thereby interfering with and preventing connection. The alignment member 728 and the channel 688 thus cooperate to facilitate proper connection of the accessory 700 to the image capture apparatus 600, which results in alignment of the hall sensor(s) 652 and the magnet(s) 712 and detection and identification of the accessory 700, as described in further detail below.

Restricting the accessory 700 to connection in a single orientation obviates the need to include additional boss(es) 724 and magnet(s) 712 on the accessory 700 (i.e., on the end 730i of the frame 702), which reduces the overall cost of the accessory 700. Embodiments including such additional boss(es) 724 and magnet(s) 712 are also envisioned herein, however, which would result in a configuration that is symmetrical about each of the axes Ai, Aii (FIG. 9) and would allow for elimination of the alignment member 728 and the channel 688, thereby facilitating connection of the accessory 700 to the image capture apparatus 600 in dual orientations that are angularly (circumferentially) offset by 180 degrees.

In the illustrated embodiment, the frame 702 and the alignment member 728 are configured as separate, discrete components of the accessory 700 that are adhesively connected (secured) together. Embodiments in which the frame 702 and the alignment member 728 may be mechanically connected (secured) together are also envisioned, herein, however, as are embodiments in which the frame 702 and the alignment member 728 may be integrally (unitarily, monolithically) formed from a single piece of material (e.g., one or more metallic or non-metallic materials), and would not be beyond the scope of the present disclosure.

In order to facilitate proper positioning of the alignment member 728 and proper connection of the alignment member 728 to the frame 702, the frame 702 and the alignment member 728 include corresponding locating features 732, 734. More specifically, in the illustrated embodiment, the frame 702 includes (defines) a key 736 that is configured for insertion into a corresponding receptacle (recess) 738 on the alignment member 728. Embodiments in which the configurations of the locating features 732, 734 may be reversed (i.e., embodiments in which the key 736 and the receptacle 738 are respectively included on the alignment member 728 and the frame 702) are also envisioned herein, however, and would not be beyond the scope of the present disclosure.

The retainers 704 are received by bases 740 that are supported on (e.g., formed integrally with) the rear surface 722 of the frame 702. The retainers 704 are connected to (secured within) the bases 740 via the mechanical fasteners 706, which extend into bosses 742 that are positioned laterally outwardly of the recesses 726 in corner sections of the frame 702.

In the illustrated embodiment, the accessory 700 includes a pair of identical retainers 704i, 704ii that are configured as flexible, resiliently deflectable wire forms 744, each of which includes a (generally) linear initial configuration (e.g., in the absence of any applied force). It should be appreciated, however, that the specific configuration of the retainers 704 may be varied in alternate embodiments of the disclosure, and that the retainers 704 may be configured in any manner suitable for the intended purpose of securing the accessory 700 to the mounting member 612 in the manner described herein below.

The sealing member 708 is supported within a circumferential channel 746 (FIG. 9) that is defined by the extension 714 such that the extension 714 and the sealing member 708 extend into the mounting member 612 (FIG. 7) upon connection of the accessory 700 to the image capture apparatus 600, thereby forming a watertight seal between the accessory 700 and the image capture apparatus 600.

The insert 710 (FIG. 6) is supported by the frame 702 and may include (e.g., may be formed partially or entirely from) a variety of materials (e.g., depending upon the desired optical effect of the accessory 700). For example, it is envisioned that the insert 710 may include or otherwise support an optical element 748 (e.g., a lens 750) such that the optical element 748 is supported by the frame 702.

In various embodiments of the accessory 700, it is envisioned that the optical element 748 may include (i.e., may be formed partially or entirely from) an optically clear material so as to permit the capture of content through the accessory 700 without interference. Alternatively, it is envisioned that the material(s) utilized in construction of the insert 710 may be chosen so as to attribute particular optical characteristics and functionality to the accessory 700 that allow the accessory 700 to function as an optical filter and alter image capture by the image capture apparatus 600.

The magnet(s) 712 (FIG. 9) are received (accommodated) by and are positioned (located) within the boss(es) 724, as indicated above. More specifically, the boss(es) 724 and, thus, the magnets(s) 712, are positioned (located) adjacent to a (second) end (side) 730ii of the frame 702 adjacent to the perimeter thereof, which is opposite to the end 730i, such that the magnet(s) 712 are generally aligned with the relief(s) 682 and the hall sensor(s) 652 (FIG. 8) upon connection of the accessory 700 to the image capture apparatus 600, as seen in FIG. 7.

In the illustrated embodiment, the boss(es) 724 are configured to receive (accommodate) the magnet(s) 712 such that the magnet(s) 712 are embedded within the accessory 700. More specifically, the boss(es) 724 include crush ribs 752 that are deformed (deflected) upon insertion of the magnet(s) 712, thereby creating an interference (friction) fit that mechanically secures the magnet(s) 712 within the boss(es) 724. Embodiments in which the magnet(s) 712 may be adhesively secured within the boss(es) 724, either in addition to or instead of the aforementioned mechanical engagement, are also envisioned herein, however, and would not be beyond the scope of the present disclosure.

The magnet(s) 712 interface (interact) with the hall sensor(s) 652 on the image capture apparatus 600 upon connection of the accessory 700. More specifically, the magnet(s) 712 generate magnetic field(s) that are transmitted through the front housing portion 620 and through the mounting member 612 (i.e., via the relief(s) 682 (FIG. 7)), which effectuates a change in voltage that is detected and/or measured by the hall sensor(s) 652. The relief(s) 682 thus inhibit (if not entirely prevent) interference with the magnetic field(s), which facilitates unimpeded (magnetic) communication between the accessory 700 (i.e., the magnet(s) 712) and the image capture apparatus 600 (i.e., the hall sensor(s) 652). The voltage change is output from the hall sensor(s) 652 to the PCB module 606 (i.e., via the electrical connector 656 (FIG. 8)), whereupon the accessory 700 is automatically detected and identified by the image capture apparatus 600 and various settings (e.g., image and/or video capture settings) on the image capture apparatus 600 are automatically reconfigured (updated) based on the detected accessory 700 in order to improve (e.g., optimize) image and/or video capture.

In certain embodiments of the disclosure, rather than being concealed within the internal compartment 624, it is envisioned that the hall sensor(s) 652 may be exposed from the body 602 of the image capture apparatus 600 in order to further facilitate unimpeded (magnetic) communication between the hall sensor(s) 652 and the magnet(s) 712. For example, it is envisioned that the front housing portion 620 and the mounting member 612 may include openings (e.g., apertures, slits, windows, etc.) that are generally aligned with the hall sensor(s) 652 and the magnet(s) 712 (upon connection of the accessory 700), thereby allowing for elimination of the relief(s) 682 (FIG. 7).

In the illustrated embodiment, the accessory 700 includes a pair of (first and second) magnets 712i, 712ii, which are spaced laterally along the width Wa thereof and each include (first and second) North and South poles 754N, 754S (FIG. 9). It is envisioned, however, that the particular number of magnets 712, the positions (location) of the magnets 712, and/or the polarities (orientations) of the magnets 712 may be varied in alternate embodiments of the disclosure. For example, embodiments of the accessory 700 including fewer and greater numbers of magnets 712 are also envisioned herein (e.g., depending upon the particular configuration of the accessory 700), as are embodiments in which the magnet 712i and/or the magnet 712ii may be oriented such that the South poles 754S face (are directed towards) the image capture apparatus 600, as described in further detail below, and would not be beyond the scope of the present disclosure.

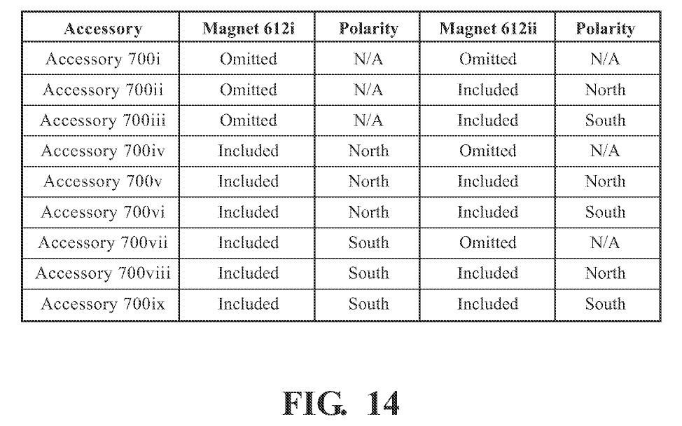

Providing for the incorporation of two magnets 712 and two hall sensors 652 facilitates the detection and identification of nine discrete embodiments of the accessory 700, which are identified by the reference characters 700i-700ix. More specifically, as seen in FIG. 14, in the accessory 700i, the magnets 712i, 712ii are omitted, in the accessory 700ii, the magnet 712i is omitted and the magnet 712ii is included with the North pole 754N thereof facing (being oriented towards) the image capture apparatus 600, in the accessory 700iii, the magnet 712i is omitted and the magnet 712ii is included with the South pole 754S thereof facing (being oriented towards) the image capture apparatus 600, in the accessory 700iv, the magnet 712i is included with the North pole 754N thereof facing (being oriented towards) the image capture apparatus 600 and the magnet 712ii is omitted, in the accessory 700v, each of the magnets 712i, 712ii is included with the North poles 754N thereof facing (being oriented towards) the image capture apparatus 600, in the accessory 700vi, each of the magnets 712i, 712ii is included with the respective North and South poles 754N, 754S thereof facing (being oriented towards) the image capture apparatus 600, in the accessory 700vii, the magnet 712i is included with the South pole 754S thereof facing (being oriented towards) the image capture apparatus 600 and the magnet 712ii is omitted, in the accessory 700viii, each of the magnets 712i, 712ii is included with the respective South and North poles 754S, 754N thereof facing (being oriented towards) the image capture apparatus 600, and in the accessory 700ix, each of the magnets 712i, 712ii is included with the South poles 754S thereof facing (being oriented towards) the image capture apparatus 600.

In order to increase or decrease the number of detectable and identifiable embodiments of the accessory 700, it is envisioned that the number of hall sensors 652, the number of magnets 712, and/or the polarity(ies) of the magnets 712 may be varied. For example, embodiments of the image capture apparatus 600 that include a single hall sensor 652 and embodiments of the image capture apparatus 600 that include three or more hall sensors 652 are also envisioned herein, as are embodiments of the accessory 700 that include a single magnet 712 and embodiments of the accessory 700 that include three or more magnets 712.

Additionally, or alternatively, embodiments of the image capture apparatus 600 are envisioned in which the hall sensor(s) 652 may be configured to measure the intensity of the magnetic field(s) that are generated by the magnet(s) 712 by measuring, rather than simply detecting, change(s) in voltage, as indicated above, thereby allowing for additional variation in the number of detectable and identifiable embodiments of the accessory 700. For example, it is envisioned that the intensity of the magnetic field(s) may be increased or decreased by varying the type of magnet(s) 712, the size(s) of the magnet(s) 712, the distance between the hall sensor(s) 652 and the magnet(s) 712, etc.

It is envisioned that measuring the intensity of the magnetic field(s) may also facilitate the detection (recognition) of the specific (rotational) position of the accessory 700 (e.g., during focus adjustment). For example, it is envisioned that data concerning the specific rotational position of the accessory 700 may be communicated to the image capture apparatus 600 (i.e., based upon the measured intensity of the magnetic field(s)), whereupon automatic adjustments may be made to the processing of the image by the image capture apparatus 600 in order to reduce distortion, color shift, etc. In such embodiments, it is envisioned that a variety of sensors (e.g., RF sensors, optical sensors, IR light pipes, capacitive couplings, etc.) and tags (e.g. RF tags, RF coils, etc.) may be utilized, either in addition to or instead of the hall sensor(s) 652 and the magnet(s) 712, respectively.

Referring now to FIGS. 7 and 9, connection of the accessory 700 to the image capture apparatus 600 will be discussed.

Initially, the accessory 700 is oriented such the recesses 726 are angularly (circumferentially) offset from (are out of alignment with) the radial mounts 684 and the alignment member 728 is generally aligned with the channel 688, as seen in FIGS. 10 and 12, for example. The accessory 700 is then advanced towards the image capture apparatus 600, whereby the radial mounts 684 are inserted into the guide channels 718 and the alignment member 728 is inserted into the channel 688.

Thereafter, the accessory 700 is rotated in relation to the image capture apparatus 600 (either clockwise or counterclockwise) such that the radial mounts 684 are brought into engagement (contact) with the retainers 704, which results in inward (axial) displacement of the accessory 700 (i.e., towards the body 602 of the image capture apparatus 600) along the optical axis X (FIG. 5). Rotation and inward (axial) displacement of the accessory 700 continues until the radial mounts 684 are generally aligned with and are inserted into the recesses 726, which results in general alignment of the magnet(s) 712 with the relief(s) 682 (FIG. 7) and the hall sensor(s) 652 and, thus, a change in voltage. The change in voltage is output from the hall sensor(s) 652 to the PCB module 606 (FIG. 6) and is utilized to automatically detect and identify the accessory 700, whereupon the image capture apparatus 600 is automatically reconfigured based on the detected accessory 700 in order to improve (e.g., optimize) image and/or video capture.

To disconnect the accessory 700, the accessory 700 is rotated in relation to the image capture apparatus 600 (either clockwise or counterclockwise), whereby the radial mounts 684 bear against the recesses 726, thereby displacing the accessory 700 (axially) outward (i.e., away from the body 602 of the image capture apparatus 600) along the optical axis X (FIG. 5). As rotation of the accessory 700 continues, the magnet(s) 712 and the hall sensor(s) 652 are moved out of alignment and the radial mounts 684 are removed from the recesses 726, during which, the radial mounts 684 disengage the retainers 704 as the radial mounts 684 move through the guide channels 718. The accessory 700 can then be completely removed from the mounting member 612 and disconnected from the image capture apparatus 600.

While the present disclosure has been described in connection with certain embodiments, it is to be understood that the present disclosure is not to be limited to the disclosed embodiments, but, on the contrary, is intended to cover various modifications and equivalent arrangements included within the scope of the appended claims, which scope is to be accorded the broadest interpretation to encompass all such modifications and equivalent structures as is permitted under the law.

Persons skilled in the art will understand that the various embodiments of the present disclosure and shown in the accompanying figures constitute non-limiting examples, and that additional components and features may be added to any of the embodiments discussed hereinabove without departing from the scope of the present disclosure. Additionally, persons skilled in the art will understand that the elements and features shown or described in connection with one embodiment may be combined with those of another embodiment without departing from the scope of the present disclosure to achieve any desired result and will appreciate further features and advantages of the presently disclosed subject matter based on the description provided. Variations, combinations, and/or modifications to any of the embodiments and/or features of the embodiments described herein that are within the abilities of a person having ordinary skill in the art are also within the scope of the present disclosure, as are alternative embodiments that may result from combining, integrating, and/or omitting features from any of the disclosed embodiments.

Use of the term “optionally” with respect to any element of a claim means that the element may be included or omitted, with both alternatives being within the scope of the claim. Additionally, use of broader terms such as “comprises,” “includes,” and “having” should be understood to provide support for narrower terms such as “consisting of,” “consisting essentially of,” and “comprised substantially of.” Accordingly, the scope of protection is not limited by the description set out above, but is defined by the claims that follow, and includes all equivalents of the subject matter of the claims.

In the preceding description, reference may be made to the spatial relationship between the various structures illustrated in the accompanying drawings, and to the spatial orientation of the structures. However, as will be recognized by those skilled in the art after a complete reading of this disclosure, the structures described herein may be positioned and oriented in any manner suitable for their intended purpose. Thus, the use of terms such as “above,” “below,” “upper,” “lower,” “inner,” “outer,” “left,” “right,” “upward,” “downward,” “inward,” “outward,” “horizontal,” “vertical,” etc., should be understood to describe a relative relationship between the structures and/or a spatial orientation of the structures. Those skilled in the art will also recognize that the use of such terms may be provided in the context of the illustrations provided by the corresponding figure(s).

Additionally, terms such as “generally,” “approximately,” “substantially,” and the like should be understood to include the numerical range, concept, or base term with which they are associated as well as variations in the numerical range, concept, or base term on the order of up to 25% (e.g., to allow for manufacturing tolerances and/or deviations in design). For example, the term “generally parallel” should be understood as referring to an arrangement in which the pertinent components (structures, elements) subtend an angle therebetween that is equal to 180° as well as an arrangement in which the pertinent components (structures, elements) subtend an angle therebetween that is greater than or less than 180° (e.g., ±10%, ±15%, ±25%). The term “generally parallel” should thus be understood as encompassing configurations in which the pertinent components are arranged in parallel relation. Similarly, the term “generally identical” should be understood as encompassing configurations in which the pertinent components are identical in configuration as well as configurations in which there may be insubstantial variations between the pertinent components that do not influence the substantive construction or performance thereof.

Although terms such as “first,” “second,” “third,” etc., may be used herein to describe various operations, elements, components, regions, and/or sections, these operations, elements, components, regions, and/or sections should not be limited by the use of these terms in that these terms are used to distinguish one operation, element, component, region, or section from another. Thus, unless expressly stated otherwise, a first operation, element, component, region, or section could be termed a second operation, element, component, region, or section without departing from the scope of the present disclosure, etc.

Each and every claim is incorporated as further disclosure into the specification and represents embodiments of the present disclosure. Also, the phrases “at least one of A, B, and C” and “A and/or B and/or C” should each be interpreted to include only A, only B, only C, or any combination of A, B, and C.

What is claimed is:

1. An image capture system comprising:
an image capture apparatus including:
a body defining a waterproof internal compartment;
at least one hall sensor positioned within the waterproof internal compartment; and
a mounting member connected to the body, wherein the mounting member includes:
a base defining at least one relief extending along a height of the image capture apparatus; and
a collar extending forwardly from the base, wherein the collar defines:
an arcuate channel; and
first and second stops positioned at opposite ends of the arcuate channel; and
an accessory configured for releasable connection to the image capture apparatus, wherein the accessory includes:
a frame;
an optical element supported by the frame;
an alignment member extending rearwardly from the frame and configured for engagement with the first and second stops such that the accessory is rotatable in relation to the mounting member through a fixed range of angular motion; and
at least one magnet connected to the frame and configured to interface with the at least one hall sensor such that, upon connection of the accessory to the mounting member, the accessory is automatically detected and identified by the image capture apparatus based on output from the at least one hall sensor.

2. The image capture system of claim 1, wherein the at least one hall sensor includes first and second hall sensors spaced laterally along a width of the image capture apparatus.

3. The image capture system of claim 1, further including:
a heat sink positioned within the body; and
a flexible printed circuit assembly connected to the heat sink.

4. The image capture system of claim 3, wherein the at least one hall sensor is connected to the flexible printed circuit assembly.

5. The image capture system of claim 1, wherein the first and second stops are separated by approximately 100 degrees to thereby define the fixed range of angular motion.

6. The image capture system of claim 1, wherein the alignment member and the at least one magnet are positioned at opposite ends of the accessory.

7. The image capture system of claim 1, wherein the arcuate channel is configured to receive the alignment member such that the alignment member is movable through the arcuate channel during rotation of the accessory.

8. The image capture system of claim 1, wherein the at least one magnet is embedded within the accessory.

9. The image capture system of claim 8, wherein the frame includes at least one boss configured to receive the at least one magnet.

10. The image capture system of claim 9, wherein the at least one magnet is mechanically secured within the at least one boss.

11. An image capture system comprising:
an image capture apparatus including:
a body; and
a mounting member connected to the body; and
an accessory configured for releasable connection to the image capture apparatus, wherein the accessory generates a magnetic field facilitating automatic detection and identification of the accessory by the image capture apparatus upon connection.

12. The image capture system of claim 11, wherein the image capture apparatus further includes at least one hall sensor, and the accessory further includes at least one magnet configured to interface with the at least one hall sensor.

13. The image capture system of claim 12, wherein the at least one hall sensor includes a first hall sensor and a second hall sensor, and wherein the at least one magnet includes a first magnet and a second magnet.

14. The image capture system of claim 13, wherein the first hall sensor and the second hall sensor are spaced laterally along a width of the image capture apparatus.

15. The image capture system of claim 12, wherein the mounting member includes a base defining at least one relief extending along height of the image capture apparatus, and wherein the at least one relief is generally aligned with the at least one hall sensor and the at least one magnet so as to inhibit interference with the magnetic field.

16. An image capture system comprising:
an image capture apparatus including:
a body; and
a mounting member connected to the body, wherein the mounting member includes:
a base; and
a collar extending forwardly from the base; and
an accessory configured for releasable connection to the mounting member such that, upon connection of the accessory to the image capture apparatus, the accessory is rotatable in relation to the mounting member through a fixed range of angular motion and automatically detected and identified by the image capture apparatus.

17. The image capture system of claim 16, wherein the collar defines first and second stops.

18. The image capture system of claim 17, wherein the accessory includes an alignment member configured for engagement with the first and second stops to thereby define the fixed range of angular motion.

19. The image capture system of claim 18, wherein the first and second stops are separated by less than 180 degrees.

20. The image capture system of claim 16, wherein the base defines at least one relief configured to facilitate magnetic communication between the image capture apparatus and the accessory.
